(19) United States
(12) Patent Application Publication
(10) Pub. No.: US 2025/0172865 A1
(43) Pub. Date: May 29, 2025

(54) SYSTEMS AND METHODS FOR PROXIMITY CORRECTION FOR LITHO-ETCHING-LITHO-ETCHING PROCESSES

(71) Applicant: Samsung Electronics Co., Ltd., Suwon-si (KR)

(72) Inventor: Yang Woo Heo, Suwon-si (KR)

(21) Appl. No.: 18/679,759

(22) Filed: May 31, 2024

(30) Foreign Application Priority Data
Nov. 23, 2023 (KR) 10-2023-0164009

(51) Int. Cl. G03F 1/36; G06F 30/398

(52) U.S. Cl. CPC G03F 1/36; G06F 30/398

(57) ABSTRACT

A proximity correction model generation method for a litho-etching-litho-etching (LELE) process in the semiconductor fabricating process. For example, proximity correction method for an LELE process performed by a computing system according to may include acquiring a first feature set of a first evaluation point of a first mask, acquiring a second feature set of a second evaluation point of a reference layer corresponding to a shape of a hard mask which is formed by a primary photolithography process and a primary etching process using the first mask, and a secondary photolithography process and a secondary etching process using a second mask, inputting input data including the first feature set and the second feature set into the proximity correction model and generating a value of an etch skew of the first evaluation point of the first mask, using data that is output from the proximity correction model.

### CROSS-REFERENCE TO RELATED APPLICATION

The present application claims priority and all the benefits accruing therefrom to Korean Patent Application No. 10-2023-0164009, filed on Nov. 23, 2023, and the entire contents of the above-identified application are incorporated by reference as if set forth herein.

### BACKGROUND

### 1. Technical Field

The present disclosure relates to proximity correction systems and methods for litho-etching-litho-etching (LELE) processes. More particularly, the present disclosure relates to systems and methods for improving accuracy in performing machine learning-based proximity correction on masks for LELE processes.

### 2. Description of the Related Art

With miniaturization of semiconductor processes, there is increased difficulty in forming intended target patterns on a wafer in an accurate manner. A target pattern is formed on the wafer by performing a photolithography process using a mask layout, and by performing an etching process using a photoresist pattern formed as a result of the photolithography process. Deviations in optical path due to various process conditions, known as an optical proximity effect (OPE) or a process proximity effect (PPE), may increase and corrections thereof may be required.

An optical proximity correction (OPC) process or a process proximity correction (PPC) process is performed to reduce the influences of OPE or PPE. The OPC process may be understood as a process of artificially correcting a mask layout by comparing the photoresist pattern that is expected as a result of applying the mask layout to the photolithography process with the target photoresist pattern. The PPC process may be understood as a process of artificially correcting the photoresist pattern by comparing an etching pattern expected as a result of applying the photoresist pattern to the etching process with a target etching pattern.

A technique of generating an OPC model that receives input of data about a mask layout to infer the photoresist pattern, by the use of machine learning, is provided. Similarly to the OPC model described above, a technique of generating a PPC model that by receives input of data about a photoresist pattern to infer an etching pattern, by the use of the machine learning, is provided.

On the other hand, a multi-patterning technique for patterning fine patterns is provided. Such a multi-patterning technique may be a technique that may increase a pattern density by performing additional patterning for providing additional patterns between pitches of patterns formed by single patterning. Among the multi-patterning techniques, an LELE (Litho-Etch-Litho-Etch) technique is one in which a hard mask used in the final etching for forming the final pattern is formed through a first mask-based photolithography-etching process and a second mask-based photolithography-etching process. An LELELE (Litho-Etch-Litho-Etch-Litho-Etch) technique is also provided to further increase the pattern density of the hard mask. However, although the LELELE technique may increase the pattern density, there is a problem of difficulty in maintaining accuracy in the wafer alignment while sequentially performing the three photolithography-etching processes, and there a degree of utilization for LELE processes is higher than that of LELELE processes.

The LELE process will be explained with reference to FIG. 1.

In a primary photolithography process of stage S1, a first photoresist pattern 53 is formed, using a first mask 51 having a first ADI (After Development Inspection) target 52. In a primary etching process of stage S2, a primary pattern 54a is formed on the hard mask, using the first photoresist pattern 53.

In a secondary photolithography process of stage S3, a second photoresist pattern 59 is formed using a second mask 57 having a second ADI (After Development Inspection) target 58. In the secondary etching process of stage S4, a secondary pattern 54b is additionally formed on the hard mask on which the primary pattern has been formed previously using the second photoresist pattern 59, thereby completing the hard mask.

Next, in the final etching process of stage S5, a final pattern is formed on a device layer 55 formed on the substrate 56 using the completed hard mask. Accordingly, the pattern formation according to the LELE process is finished. In the CD (Critical Dimension) measurement process of stage S6, it is checked whether the pattern is formed accurately.

Even in such a LELE process, the mask layout may be corrected by performing the above-described OPC or PPC processes. Furthermore, the above-mentioned OPC or PPC processes may be performed in an image-to-image type CNN-based deep learning manner or in a predetermined feature set-based machine learning manner.

Incidentally, in the machine learning process based on the feature set for the LELE process, only the feature set extracted from the correction target mask is used as learning data. For example, according to this related art, the model for performing machine learning-based PPC of a particular mask for the LELE process is subjected to machine-learning, only using geometric features of the pattern identified in the ADI (After Develop Inspection) images of the particular mask. Considering that the LELE process involves a total of three etching processes, the model for PPC execution outputs information about mask correction without taking into account the information about the remaining two etching processes. Even if the mask layout is corrected using the output information in this way, there may be an error between the final pattern according to the LELE process using the mask with the corrected layout and the desired target layout. That is, consideration is made as to the accuracy of the feature set-based machine learning-based proximity correction technique for the conventional LELE process.

### SUMMARY

Some aspects of the present disclosure provide methods and systems for generating highly accurate machine learning-based mask layout proximity correction models for LELE processes.

Some aspects of the present disclosure also provide proximity correction methods and systems using machine learning-based mask layout proximity correction models for LELE processes.

However, the inventive concepts of the present disclosure are not restricted to those set forth above. The above and other aspects of the present disclosure will become more apparent to those of ordinary skill in the art to which the present disclosure pertains by referencing the detailed description of the inventive concepts, given below.

According to some aspects of the present disclosure, a proximity correction system for a litho-etching-litho-etching (LELE) process is provided. The proximity correction system comprises a memory configured to load data that defines a proximity correction model and a proximity correction program of a litho-etching-litho-etching (LELE) process and one or more processors configured to execute the proximity correction program. The proximity correction program may include an instruction for acquiring a first feature set of a first evaluation point of a first mask, an instruction for acquiring a second feature set of a second evaluation point of a reference layer corresponding to a hard mask which is formed by a primary photolithography process and a primary etching process using the first mask, and a secondary photolithography process and a secondary etching process using a second mask, an instruction for inputting input data including information of the first feature set and information of the second feature set into the proximity correction model and an instruction for generating a value of an etch skew of the first evaluation point of the first mask, using data that is output from the proximity correction model. The second evaluation point may correspond to the first evaluation point.

According to some aspects of the present disclosure, a proximity correction method for an LELE process performed by a computing system is provided. The proximity correction method comprises acquiring a first feature set of a first evaluation point of a first mask, acquiring a second feature set of a second evaluation point of a reference layer corresponding to a shape of a hard mask which is formed by a primary photolithography process and a primary etching process using the first mask, and a secondary photolithography process and a secondary etching process using a second mask, inputting input data including the first feature set and the second feature set into the proximity correction model and generating a value of an etch skew of the first evaluation point of the first mask, using data that is output from the proximity correction model. The second evaluation point may correspond to the first evaluation point.

According to some aspects of the present disclosure, a proximity correction model generation system for an LELE process is provided. The proximity correction model generation system comprises a memory which loads data that defines a proximity correction model and a proximity correction model learning program of a litho-etching-litho-etching (LELE) process and one or more processors which execute the proximity correction model learning program. The proximity correction model learning program includes an instruction for acquiring data of a measurement gauge on a measurement image in which a first mask layer, which is an ADI (After Development Inspection) image of a photoresist pattern formed by a primary photolithography process using a first mask, and a reference layer corresponding to a hard mask formed by the primary photolithography process and a primary etching process using the first mask, and a secondary photolithography process and a secondary etching process using a second mask are overlaid, an instruction for determining a first evaluation point which is a point on which the measurement gauge and a contour of the first mask layer intersect, an instruction for determining a second evaluation point which is a point on which the measurement gauge and a contour of the reference layer intersect, an instruction for determining a final point corresponding to the first evaluation point on a contour of a final pattern formed after a final etching process using the hard mask, an instruction for generating a value of an etch skew of the first evaluation point, by comparing coordinates of the first evaluation point with coordinates of the final point, an instruction for generating a first feature set of the first evaluation point, an instruction for generating a second feature set of the second evaluation point, an instruction for generating learning data including information on the first feature set, information on the second feature set, and the etch skew and an instruction for performing supervised learning on the proximity correction model, using the learning data. The second evaluation point may correspond to the first evaluation point.

According to some aspects of the present disclosure, a proximity correction model generation method for an LELE process is provided. The proximity correction model generation method may include the steps of acquiring data of a measurement gauge on a measurement image in which a first mask layer, which is an ADI (After Development Inspection) image of a photoresist pattern formed by a primary photolithography process using a first mask, and a reference layer corresponding to a hard mask formed by the primary photolithography process and the primary etching process using the first mask, and a secondary photolithography process and a secondary etching process using a second mask are overlaid; determining a first evaluation point which is a point on which the measurement gauge and a contour of the first mask layer intersect; determining a second evaluation point which is a point on which the measurement gauge and a contour of the reference layer intersect; determining a final point corresponding to the first evaluation point on a contour of a final pattern formed after a final etching process using the hard mask; generating a value of an etch skew of the first evaluation point, by comparing coordinates of the first evaluation point with coordinates of the final point; generating a first feature set of the first evaluation point; generating a second feature set of the second evaluation point; generating learning data including information on the first feature set, information on the second feature set, and the etch skew; and performing supervised learning on the proximity correction model, using the learning data. At this time, the second evaluation point may correspond to the first evaluation point.

### BRIEF DESCRIPTION OF THE DRAWINGS

The above and other aspects and features of the present invention will become more apparent by describing in detail some examples of embodiments thereof with reference to the attached drawings, in which:

FIG. 1 is a diagram for explaining a LELE process according to the related art;

FIG. 2 is a configuration diagram of a proximity correction system according to some embodiments of the present disclosure;

FIG. 3 is a conceptual diagram for explaining operation results of the proximity correction system described with reference to FIG. 2;

FIG. 4 is a diagram for explaining a proximity correction method in the LELE process according to some embodiments of the present disclosure;

FIG. 5 is a detailed flowchart for explaining a generating process of the learning data in the proximity correction method described with reference to FIG. 4;

FIG. 6 is a diagram for explaining a generating process of the learning data described with reference to FIG. 5, and showing a relation between a gauge, a first evaluation point, and a second evaluation point;

FIG. 7 is a diagram for explaining a generating process of the learning data described with reference to FIG. 5, and showing features of a main layer and features of a reference layer;

FIG. 8 is a diagram for explaining a generating process of the learning data described with reference to FIG. 5, and showing a configuration of an example of learning data that includes the features of the main layer and the features of the reference layer;

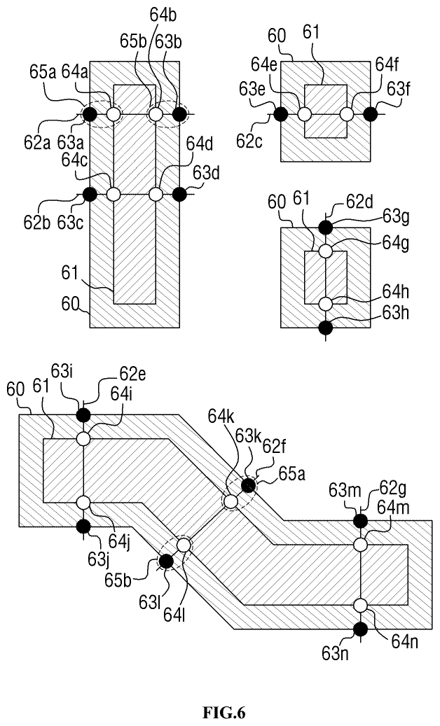

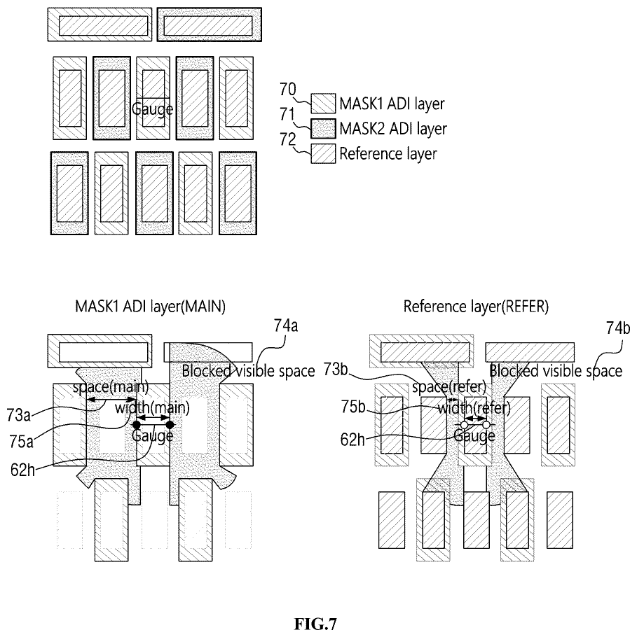

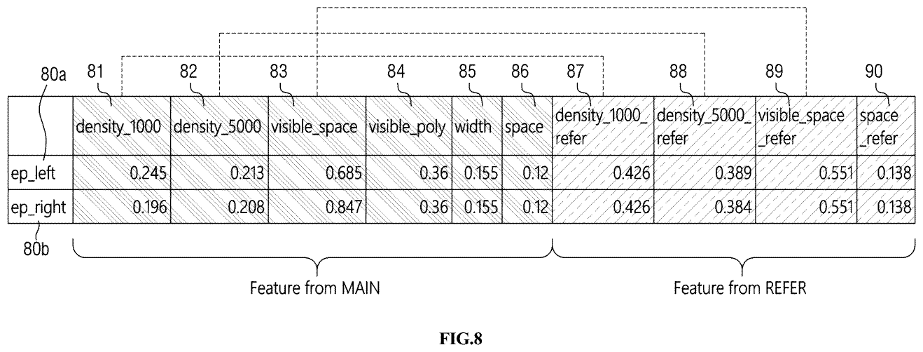

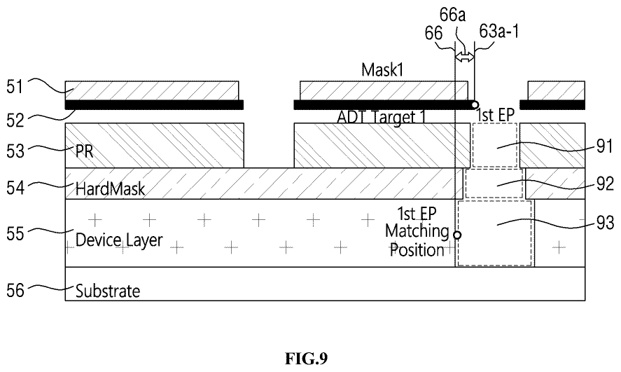

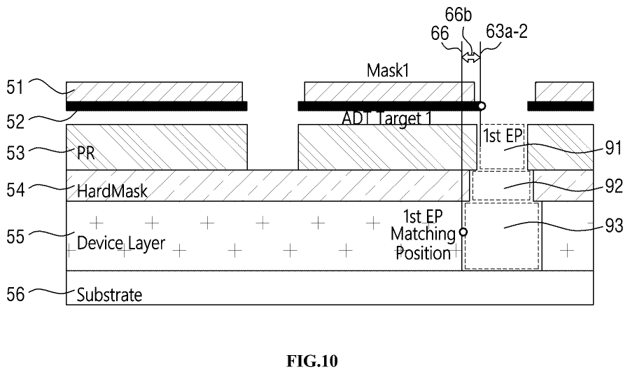

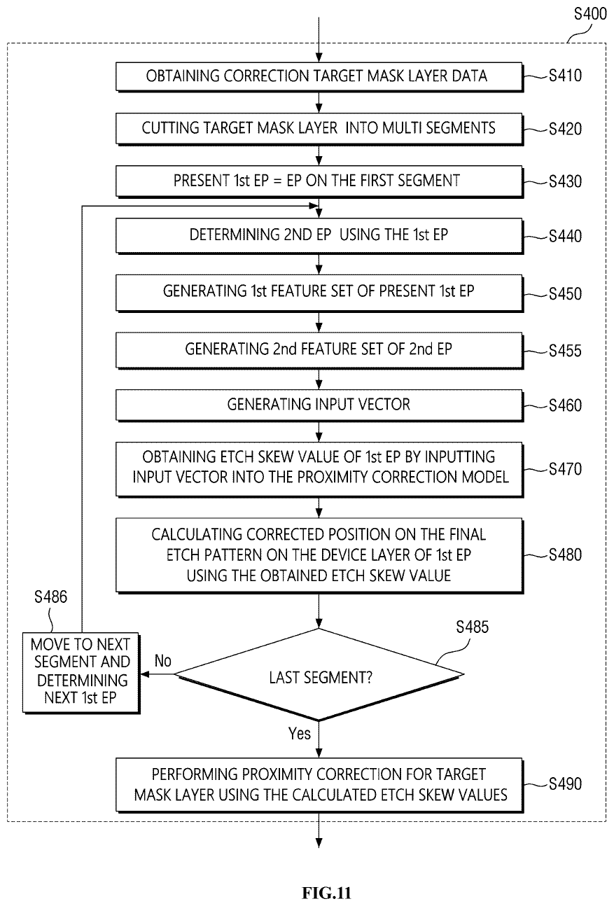

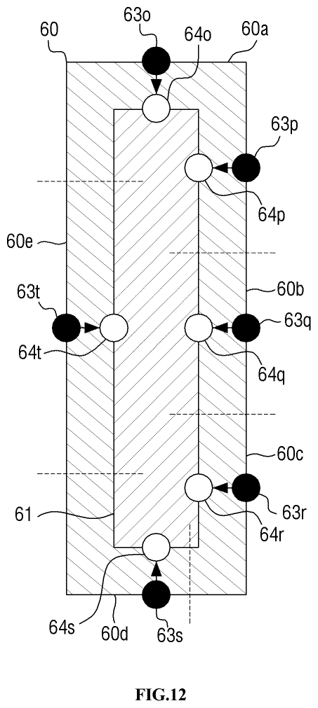

FIG. 7 is a detailed flowchart for explaining in detail some operations of the proximity correction model generation method described with reference to FIG. 6;

FIGS. 9 and 10 are diagrams for explaining a concept of an etch skew referred to in some embodiments of the present disclosure;

FIG. 11 is a detailed flowchart for explaining in more detail the proximity correction process using the learned proximity correction model in the proximity correction method described with reference to FIG. 4;

FIG. 12 is a diagram for explaining the proximity correction process described with reference to FIG. 11, and showing an example of a manner in which the second evaluation point of the reference layer is determined from the first evaluation point of the main layer; and

FIG. 13 is a hardware configuration diagram of a computing system for proximity correction process according to some embodiments of the present disclosure.

### DETAILED DESCRIPTION

Hereinafter, some examples of embodiments of the present disclosure will be described with reference to the attached drawings. The advantages and features of the present disclosure and methods of accomplishing the same may be understood more readily by reference to the following detailed description of example embodiments and the accompanying drawings. The inventive concepts of the present disclosure may, however, be embodied in many different forms and should not be construed as being limited to the embodiments set forth herein. Rather, these embodiments are provided so that this disclosure will be thorough and complete and will fully convey the inventive concepts of the disclosure to those skilled in the art, and the present disclosure will be defined by the appended claims and their equivalents. In describing the present disclosure, some description of related known configurations and/or functions may be omitted in order to not obscure the objects of the present disclosure.

The singular expressions used in the following detailed description include plural concepts, unless the context clearly specifies singularity. Additionally, plural expressions include singular concepts, unless the context clearly specifies plurality. In addition, terms such as first, second, A, B, (a), (b), or the like used in the following detailed description are only used to distinguish one element from another element, and the terms do not limit the nature, sequence, or order of the relevant elements.

The elements described with reference to terms such as unit, module, block, ˜or, ˜er, etc. used in the present disclosure and the functional blocks shown in the drawings may be implemented in the form of software, hardware, or a combination thereof. For example, the software may be machine code, firmware, embedded code, and application software. For example, the hardware may include an electrical circuit, an electronic circuit, a processor, a computer, an integrated circuit, integrated circuit cores, passive components, or a combination thereof.

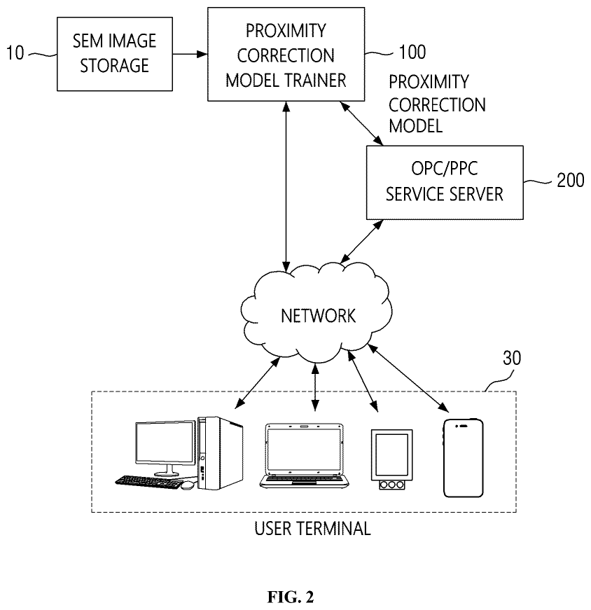

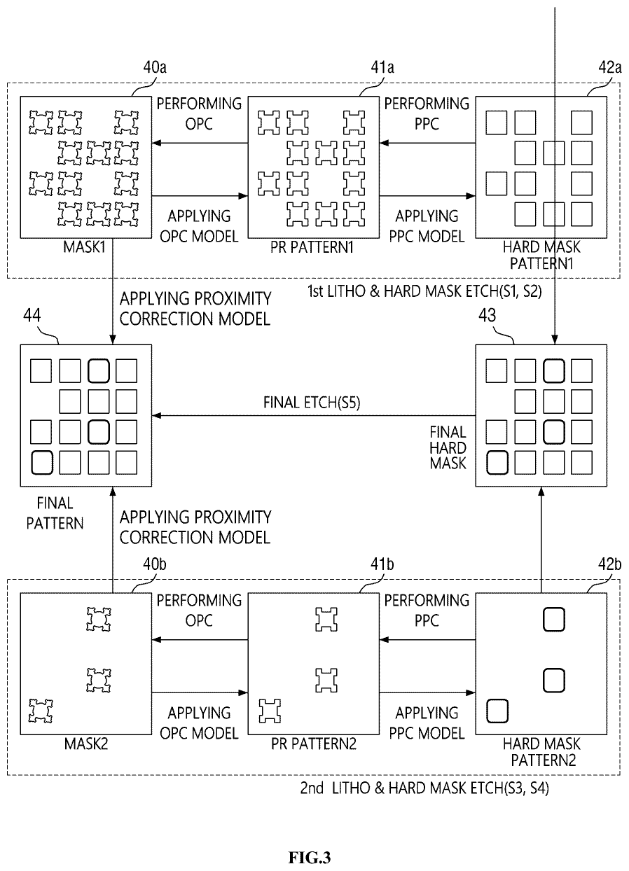

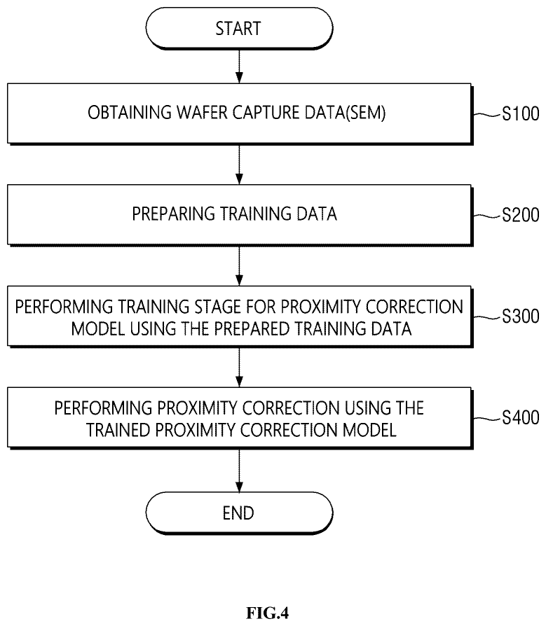

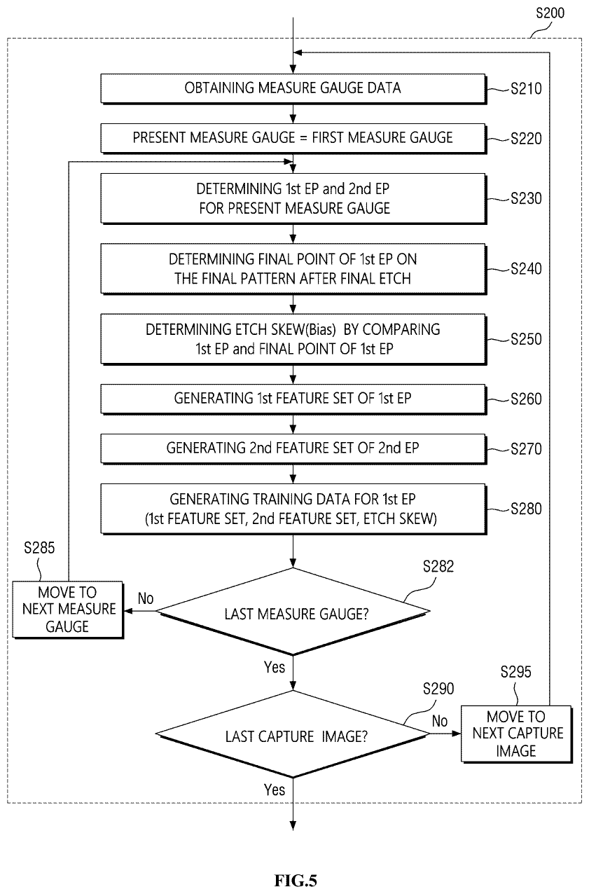

A configuration and an operation of a proximity correction system according to an example of the present disclosure will be described below with reference to FIGS. 2 and 3.

FIG. 2 is a configuration diagram of a proximity correction system according to some embodiments of the present disclosure. As shown in FIG. 2, the proximity correction system according to some embodiments may include a proximity correction model learner 100. In some embodiments, the proximity correction system may further include at least one of a service server 200 that services a proximity correction process such as an OPC (Optical Proximity Correction) and a PPC (Process Proximity Correction), and a SEM image storage 10 for storing a scanning electron microscope (SEM) image which may be a measurement result for an object such as a wafer.

The proximity correction model learner 100 may be made up of one or more computing devices. For example, the proximity correction model learner 100 may be made up of one or more cloud compute instances or cloud computing instances. In some embodiments, the proximity correction model learner 100 may be made up of compute instances of at least some of one or more virtual machines and one or more containers.

Further, the proximity correction model learner 100 may be configured to include both physical servers in the form of on-premise instances and cloud computing instances. For example, in some situations (e.g., processing semiconductor design-related data with high security requirements), modules that analyze or at least temporarily store the data may be implemented in an on-premises physical servers located in internal networks that are blocked from the Internet by firewalls, and other modules may be configured using cloud computing instances.

As used in this disclosure, “proximity correction” may refer to a process of correcting an occurrence of deviation of an optical path due to various process conditions known as an optical proximity effect (OPE) or a process proximity effect (PPE) on the fabricating process. An OPC, an ILT (Inverse Lithography Technique), and a PPC may be considered as some examples of proximity corrections, with the understanding that the present disclosure is not limited thereto.

Hereinafter, the OPC or the PPC will be described as an example of a proximity correction process for facilitating understanding of the present disclosure. However, the proximity correction process of the present disclosure is not limited to those performed in a semiconductor fabricating process. It should be understood that proximity correction, as used herein, may refer generically to processes that perform correction on the optical proximity effect or the process proximity effect in the fabricating processes in fields other than semiconductor fabrication, such as a display panel.

The proximity correction model learner 100 may generate a proximity correction model in a machine learning manner. The proximity correction model learner 100 may receive a control signal from a user terminal 30, and may perform at least one of a learning data preparation for generating the proximity correction model, a machine learning task performance using the learning data, and/or a deploy of the learned proximity correction model. The proximity correction model learner 100 may be a computing device installed with MLOps (Machine Learning Operations) solution.

The proximity correction model learner 100 may store the proximity correction model for which machine learning has been completed as data in a predetermined format. For example, the proximity correction model may be deployed to the service server 200, using the function of a deep learning framework such as Tensorflow, Pytorch or JAX, or using the function of the MLOps solution described above.

In some embodiments, a proximity correction model of a simple structure may be subjected to machine-learning. The simple structure of the proximity correction model means that the number of parameters is relatively small and the structure is relatively simple from the viewpoint of hyperparameter. In this case, the proximity correction model may also be deployed to an edge device having a compute resource poorer or lesser than the service server 200. For example, the proximity correction model may be deployed to the user terminal 30.

The machine learning operation of the proximity correction model performed by the proximity correction model learner 100 will be described in greater detail below with reference to FIGS. 11 and 12.

The proximity correction model may be a model that outputs a value of an etch skew after performing the LELE process. More specifically, the proximity correction model may be a model that receives data related to a particular evaluation point of a particular mask, and outputs a value of the etch skew of the particular evaluation point. The etch skew of the first evaluation point may refer to a difference between a position corresponding to the first evaluation point of the ADI (After Development Inspection) of the photoresist pattern formed as a result of the primary photolithography process using the first mask, and a position corresponding to the first evaluation point of the final pattern formed after the final etching process.

The evaluation point may be understood as a point located on the contour of the layouts of each of the first mask or the second mask used in the LELE process.

The position of the evaluation point may be determined by some rules using a shape of the layout. The position designation of the evaluation point may be performed by an OPC or PPC tool, may be manually designated directly by a user input that is input through the service server 200 or user terminal 30, or may be designated by customized rules defined on the basis of the user input that is input through the service server 200. Further, a plurality of evaluation points may be set for each of the first mask and the second mask. For example, the contours of each of the first and second masks may be divided into a plurality of segments, and one or more evaluation points may be set for each segment.

A user of the user terminal 30 may grasp or indicate to which position the evaluation point moves in the final pattern, by inputting data related to each evaluation point into the proximity correction model through the service server 200. For example, the user of the user terminal 30 may obtain the position of the first evaluation point in the final pattern by summing the evaluation point and the value of the etch skew output from the proximity correction model.

In other words, the user of the user terminal 30 may compare the position of each evaluation point of the final pattern that may be obtained through the output of the proximity correction model with a desired target pattern, and may refer to the result of the comparison to correct the layouts of the first mask and the second mask so that the position of the evaluation point of the final pattern according to the output of the proximity correction model approaches or approximates the target pattern.

The above-mentioned proximity correction model may be a model having an artificial neural network-based structure which includes an input layer that receives input vector of a target evaluation point on the main layer, which may be formed using ADI data after performing the photolithography process using the target mask, a hidden layer that compresses and refines the information which may be input through the input layer, and an output that outputs data about the inferring result of the etch skew of the target evaluation point on the final pattern formed after the final etching for the LELE process.

As used herein, a “main layer” may be or may refer to a layer of the mask to which proximity correction is applied. Since a first mask and a second mask are used in the LELE process, in this disclosure, the main layer may be a layer of the first mask or a layer of the second mask.

The data which is input to the input layer of the proximity correction model described above presents a new technical idea as compared to the related art in that it further includes not only a feature set of the main layer but also a feature set of the reference layer. The reference layer may be a layer corresponding to the final pattern of the hard mask that is formed by the primary photolithography process and primary etching process using the first mask, and the secondary photolithography process and secondary etching process using the second mask.

In some embodiments, the reference layer may be formed by performing an OR instruction on a target ACI (Cleaning Inspection) of the first mask and the target ACI of the second mask.

The feature set of the reference layer may be further input when the proximity correction model infers the value of the etch skew for the evaluation point of the main layer, which may be because that the final pattern finally formed through the LELE process is formed through the final etching process using a hard mask, which may be completed only after performing the secondary photolithography process and the secondary etching process using the second mask, as well as the primary photolithography process and the primary etching process using the first mask. That is, the etch skew which is output by the proximity correction model may be a value that reflects not only the hard mask etching through the primary etching process (when the main layer is the first mask) or the secondary etching process (when the main layer is the second mask) but also the final etching process using the hard mask. Accordingly, in order for the proximity correction model to accurately infer the etch skew, it may be advantageous to take into account not only information of the main layer but also information of the reference layer.

Hereinafter, the proximity correction method using the above-mentioned proximity correction model will be explained in greater detail with reference to FIGS. 5 to 10 and the like.

The functions of the service server 200 will be explained below. The service server 200 may provide the user terminal 30 with a service for executing an OPC process or a PPC process using the proximity correction model. For example, the service server 200 may be a part of an electronic design automation (EDA) server, or a server that operates in conjunction with the electronic design automation service server.

For example, the service server 200 may send data that causes the user terminal 30 to display one or more user interface screens to the user terminal 30.

For example, the user interface screen may include at least one of a screen for setting one or more evaluation points, a screen for displaying the etch skew value of the set evaluation point, and the layout of the final pattern predicted according to the etch skew value, a screen for performing a comparison between the layout of the final pattern with a desired target layout, and a screen for inputting an instruction for performing corrections of the main layer on the basis of comparison result.

The operation of the proximity correction system for the LELE process of this example will be explained with reference to FIG. 3.

The proximity correction system according to some embodiments may provide the user terminal 30 with a result of the inferring for the photoresist pattern 41a to be obtained when performing the primary photolithography process S1 using the first mask, by inputting the feature values of the layout 40a of the first mask designated from the user terminal 30 into the OPC model. Further, the proximity correction system may provide the user terminal 30 with the result of the inferring for the photoresist pattern 41b to be obtained when performing the secondary photolithography process S3 using the second mask, by inputting the feature values of the layout 40b of the second mask designated from the user terminal 30 into the OPC model.

The OPC model may be a model for inferring a photoresist pattern formed by the photolithography process using the mask, and may be a model that receives geometric features for evaluation points formed on the contour of the mask layout, and outputs a skew value for the photoresist pattern of the evaluation point, or may be an image-to-image model that receives an image of a mask layout and outputs an inferring result of the photoresist pattern. The machine learning on the OPC model may be performed by widely known supervised learning.

The user of the user terminal 30 may check the inferring results 41a and 41b of the photoresist pattern and may apply an input for correcting the mask layout to the user terminal 30 accordingly. Accordingly, the user of the user terminal 30 may correct layouts of the first mask and the second mask so that the first mask and the second mask may form patterns as close as possible to the respective target photoresist patterns by the photolithography processes S1 and S3.

In addition, the proximity correction system may provide the user terminal 30 with results of the inferring on the hard mask pattern 42a to be obtained when performing the primary etching process S2 using the photoresist pattern 41a, by inputting the feature values of the photoresist pattern 41a designated from the user terminal 30 into the PPC model. Further, the proximity correction system may provide the user terminal 30 with results of the inferring on the hard mask pattern 42b to be obtained when performing the secondary etching process S4 using the photoresist pattern 41b, by inputting the feature values of the photoresist pattern 41b designated from the user terminal 30 into the PPC model.

The above-mentioned PPC model may be a model that infers information on an etching pattern formed by an etching process performed using the photoresist pattern, and similarly to the above-mentioned OPC model, it may be a model that receives a geometric feature on the evaluation point formed on the contour of the photoresist pattern, and outputs a skew value for the etching pattern of the evaluation point, or an image-to-image model that receives an image of the photoresist pattern layout, and outputs an inferring result of the etching pattern. The machine learning on the PPC model may also be performed by widely known supervised learning similarly to the OPC model.

In the LELE process, since the pattern 42b formed by performing the secondary etching process (S4) is added to the pattern 42b formed on the hard mask by performing the primary etching process (S2), the pattern 43 of the final hard mask will be formed. In the final etching (S5) process, a final pattern 44 using the final hard mask pattern 43 will be formed on the device layer.

The final pattern 44 formed (e.g., finally formed) by the LELE process may be formed through the final etching process (S5) using the pattern 43 of the hard mask, which is completed only after performing the secondary photolithography process (S3) and the secondary etching process (S4) using the second mask, as well as the primary photolithography process (S1) and the primary etching process (S2) using the first mask. Therefore, it may not be sufficient to ensure that the final pattern is formed in an intended target layout, only by correction of the mask layout based on the output of the PPC model and the output of the OPC model.

Taking this into consideration, the proximity correction system according to this example assists in a layout correction of mask that allows a final pattern as close as possible to the target final pattern to be formed through the LELE process, by providing the proximity correction model that considers both the information of the main layer, which is either the first mask or the second mask, and the information of the reference layer corresponding to the completed hard mask.

That is, when assuming that the main layer to be corrected is the first mask, the proximity correction system according to some embodiments inputs the input data including information on each of the first feature set of the first evaluation point of the first mask and the second feature set of the second evaluation point of the reference layer corresponding to the hard mask into the proximity correction model, and may generate and output the value of the etch skew on the final pattern 44 of the first evaluation point, by the use of the data that is output from the proximity correction model. The proximity correction system may support to enhance the accuracy of target final pattern formation through the LELE process, by inferring more accurately how far apart evaluation points on the mask layout are on the final pattern 44 through a machine-learned proximity correction model.

The configuration and operation of the proximity correction system according to some embodiments have been described above. The operating method of the proximity correction system of the present disclosure may be understood in greater detail with reference to other examples described below. Further, the technical idea that may be understood by the above-described examples of the proximity correction system according to some embodiments may be reflected in other examples to be described later even if it is not designated.

Hereinafter, a proximity correction method according to some embodiments of the present disclosure will be described with reference to FIG. 4. The proximity correction method according to some embodiments may be performed by one or more computing systems. Further, in the proximity correction model generation method according to some embodiments, some operations may be performed by a first computing device, and the remaining operations may be performed by a second computing device. For example, some operations of the proximity correction method according to some embodiments may be performed by an on-premise physical server, and the remaining operations may be performed by a cloud compute instance. Further, for example, some of the operations of the proximity correction method according to some embodiments may be performed by the proximity correction model learner 100 described with reference to FIG. 2, and the remaining operation may be performed by the service server 200 described with reference to FIG. 2. Hereinafter, when the execution entity of each operation is omitted, the execution entity may be understood to be the above-mentioned computing system.

The proximity correction method according to some embodiments will be schematically explained with reference to FIG. 4. The proximity correction model generation method according to some embodiments may be understood as a proximity correction method applied to, for example, a fabricating process. Hereinafter, in order to facilitate understanding, a method for generating a proximity correction model targeting a semiconductor fabricating process will be described.

In stage S100, photographic data of a wafer or the like that is photographed in the process of forming the final pattern on the device layer according to the LELE process may be acquired. The photographic data may include at least some of photographic images of each of a first mask, a second mask, a first photoresist pattern formed in the first photolithography process, a second photoresist pattern formed in the second photolithography process, a first pattern of a hard mask formed in the first etching process, a final pattern of the hard mask including the second pattern of the hard mask additionally formed in the second etching process, and a final pattern of the device layer formed in the final etching process performed using the hard mask.

Learning data may be prepared in stage S200, using the photographic data acquired in stage S100. Next, the machine learning using the learning data may be performed in stage S300, and as a result, a proximity correction model may be generated.

Stages S100 to S300 may be understood as stages corresponding to a training stage for generating the proximity correction model. In some embodiments, the training stage may be a method performed independently as a method of generating the proximity correction model for the LELE process.

Next, a proximity correction procedure may be performed using the proximity correction model generated in stage S400. The proximity correction process according to stage S500 will be described in greater detail with reference to FIG. 11.

Hereinafter, the operation related to preparing the learning data of stage S200 will be described in detail with reference to FIG. 5. For ease of understanding, the explanation will be made assuming that stage S200 is performed by the proximity correction model learner 100.

The proximity correction model learner may perform repeatedly an operation of acquiring photographic data including a plurality of photographic images and generating learning data for each photographic image. Further, the explanation will be made on the assumption that a plurality of measurement gauges are set in one photographic image.

The proximity correction model learner may acquire measurement gauge data of a photographic image that is currently a learning data generation target among the photographic data (S210). The proximity correction model learner may start a learning data generation work on the first measurement gauge among the plurality of measurement gauges included in the measurement gauge data (S220).

The proximity correction model learner may determine the first evaluation point and the second evaluation point, using the current measurement gauge (S230). This will be explained in greater detail with reference to FIG. 6.

FIG. 6 shows that a plurality of measurement gauges are set on the image of the final pattern of an example of a hard mask. FIG. 6 shows a contour 61 of the final pattern on the hard mask and a contour 60 of the first mask layer, which may be an ADI (After Development Inspection) image of the photoresist pattern formed by the primary photolithography process using the first mask in an overlay manner, and shows a plurality of measurement gauges 62a to 62g. Although the first mask layer is the main layer and the final pattern of the hard mask is the reference layer as described above, it will be understood that FIG. 6 shows each of the contour 60 of the main layer and the contour 61 of the reference layer.

The proximity correction model learner may extract at least a pair of the first evaluation point and the second evaluation point in each of the measurement gauges 62a to 62g. The first evaluation point may be a point on which the measurement gauge and the contour 60 of the main layer intersect, and the second evaluation point may be a point on which the measurement gauge and the contour 61 of the reference layer intersect. For example, the proximity correction model learner may extract the first evaluation point 63a and the second evaluation point 64a of the first pair 65a in the first measurement gauge 62a, and may extract the first evaluation point 63a and second evaluation point 64a of the second pair 65b.

The proximity correction model learner may extract a plurality of pairs (the first evaluation point and the second evaluation point) at the intersections of the measurement gauges 62a to 62g, the contour 60 of the main layer, and the contour 61 of the reference layer. It may be seen that the first evaluation point and the second evaluation point may correspond to each other. The second evaluation point corresponding to the first evaluation point extracted by the first measurement gauge may be determined to be an intersection closest to the first evaluation point among the intersections of the first measurement gauge and the contour 61 of the reference layer. In other words, it may be understood that the second evaluation point is a position to which the first evaluation point moves according to the proximity effect in the process of performing the LELE process.

The explanation will be made by returning to FIG. 5 again.

The proximity correction model learner may determine a final point corresponding to the first evaluation point on the contour of the final pattern formed on the device layer after the final etching process using the hard mask (S240). The proximity correction model learner may acquire information on the contour of the final pattern formed on the device layer in the photographic image of the final pattern of the device layer. Further, the proximity correction model learner generates a measurement gauge of the first evaluation point on the photographic image of the final pattern of the device layer, and then may generate an intersection between the generated measurement gauge and the contour of the final pattern of the device layer, as the final point corresponding to the first evaluation point.

The final point may be understood as a point indicating to which a position on the final pattern of the device layer, the first evaluation point located on the contour of the mask corresponding to the main layer has moved by the proximity effect due to completion of all processes for the LELE process.

The proximity correction model learner may determine the value of the etch skew, using the comparison result between the absolute coordinate information of the final point and the absolute coordinate information of the first evaluation point (S250). The etch skew may also called bias. The value of the etch skew may be determined in various ways depending on how the absolute coordinates of the first evaluation point are determined. This will be explained in greater detail with reference to FIGS. 9 and 10.

The value of the etch skew may be a value that indicates an amount of positional movement due to the proximity effect according to completion of all processes for the LELE process. Therefore, the value of the etch skew may be the correct data (or tagging information) on the first evaluation point, and will be included in the learning data of the first evaluation point. That is, the proximity correction model learner may perform the machine learning on the proximity correction model in a supervised learning way, using a learning data set that includes the value of the etch skew as tagging information.

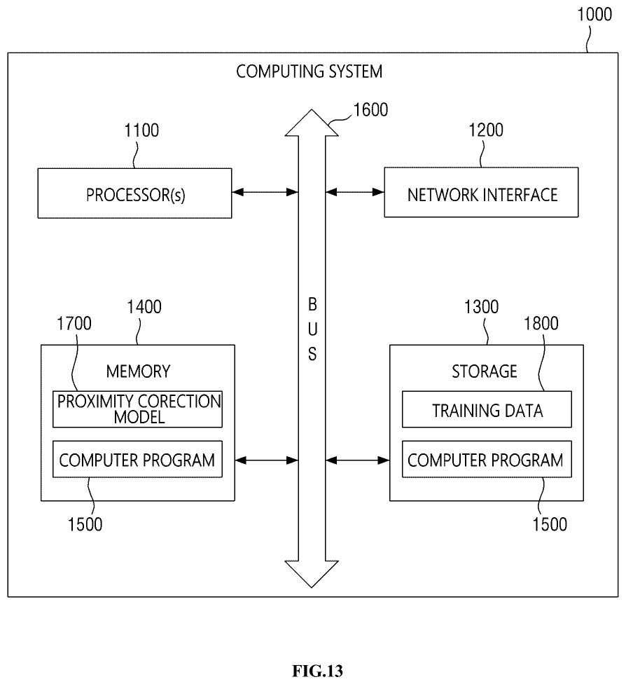

The proximity correction model learner may generate a value of the first feature set including various types of information such as the geometric feature of the first evaluation point (S260), generate a value of the first feature set including various types of information such as the geometric feature of the second evaluation point (S270), and generate the learning data of the first evaluation point including the first feature set, the second feature set, and the value of the etch skew (S280). The first feature set and the second feature set will be described in greater detail with reference to FIGS. 7 and 8.

FIG. 7 shows an ADI image layer 70 of the first mask that is a main layer, an ADI image layer 71 of the second mask, and a final pattern layer 72 of the hard mask that is a reference layer. As described above, the intersection between the measurement gauge 62h and the contour of the main layer 70 may be the first evaluation point, and the intersection between the measurement gauge 62h and the contour of the reference layer 72 may be the second evaluation point.

The geometric features of the first evaluation point may include, for example, a space 73a that may mean or may refer to a distance to an opposing pattern, a visual space 74a that is a width of a region that is seen without clogging at the first evaluation point, and a width 75a that is a distance to the corresponding first evaluation point.

On the other hand, FIG. 7 shows that the values of the same feature as the geometric feature of the first evaluation point described above are different between the first evaluation point and the second evaluation point. That is, the space 73b of the second evaluation point becomes shorter than the space 73a of the first evaluation point due to an appearance of a new pattern based on the opposing second mask, and the visual space 74b of the second evaluation point has also become narrower than the visible space 74a of the first evaluation point because many areas are further hidden due to an appearance of the new pattern based on the second mask. Further, the width 75b of the second evaluation point may become shorter than that of the width 75a of the first evaluation point according to the execution of the first mask-based primary etching process, the second mask-based secondary photolithography process and secondary etching process.

Since the visible spaces 74a and 74b are features in which there is a high possibility that there is a difference between the value of the first evaluation point and the value of the second evaluation point due to its attributes, the visible space features may be included in both the first feature set and the second feature set in the learning data.

As shown in FIG. 7, the first evaluation point and the second evaluation point may be points which are located on the same gauge, are located close to each other and correspond to each other, but it will be appreciated that the geometric feature acquired on the second evaluation point located at the reference layer may exhibit a significant difference from the geometric feature acquired on the first evaluation point.

Considering that the value of the etch skew of the first evaluation point is determined on the basis of the final pattern formed by the final etching process on the hard mask represented by the reference layer, and the geometric features acquired at the second evaluation point located at the reference layer exhibit a considerable difference from the geometric features acquired at the first evaluation point, it may be able to understand (e.g., understand easily) that there is a considerable effect on improving the accuracy of the proximity correction model, by additionally reflecting the information acquired at the second evaluation point of the reference layer as learning data of the machine learning of the proximity correction model that infers the value of the etch skew of the first evaluation point.

In summary, the PPC machine learning model of the existing LELE process may generate the learning data that only includes the feature set of the first evaluation point of the main layer and the value of the etch skew, and may fail to learn the information of the reference layer. Meanwhile, the method according to this example may include information on the second evaluation point of the reference layer as learning data of the first evaluation point, and therefore, may have a positive effect on the inferring accuracy of the proximity correction model, by considering information about the reference layer that has an effect on the etch skew proximity correction, in the machine learning process of the proximity correction model that infers the etch skew for the input evaluation point.

FIG. 8 is a diagram showing the configuration of an example of learning data including features of the main layer and features of the reference layer. The proximity correction model learner may include first feature sets 81 to 86 of the first evaluation point, second feature sets 87 to 90 of the second evaluation point, and a value of the etch skew (not shown) as tagging information (or correct answer data), in the learning data of the first evaluation points 80a and 80b.

The number of features included in the first feature set may be greater than or equal to the number of features included in the second feature set. For example, the number of features included in the first feature set may be greater than the number of features included in the second feature set. Accordingly, the proximity correction model may be subjected to machine-learning so that the information of the main layer is reflected more importantly than the information of the reference layer, in determining the output value.

In some embodiments, at least some of the features included in the first feature set and the second feature set may be the same. FIG. 8 shows that features such as density_1000 (81, 87), density_5000 (82, 88), visible_space (83, 89), and space (86, 90) may be included in common in the first feature set and the second feature set. As a result, when the value of the first evaluation point and the value of the second evaluation point for the same feature are different from each other, the proximity correction model may be subjected to machine-learning so that such type of information is reflected in determining the output value. At this time, all the features included in the second feature set may be included in the first feature set.

On the other hand, in some embodiments, values of features commonly included in the first feature set and the second feature set may be subjected to feature fusion, and the fused feature values may be included in the learning data. That is, in the example of learning data shown in FIG. 8, each of two feature values 81 and 87 of density_1000, two feature values 82 and 88 of density_5000, two feature values 83 and 89 of visible_space, and two feature values 86 and 90 of space may be fused and joined into a single value. In this case, the learning data of FIG. 8 are a total of six features such as the feature fusion result of density_1000 (81, 87), the density_5000 (82, 88), the feature fusion result of visible_space (83, 89), the feature fusion result of space (86, 90), the visible_poly (84), and the width (85), and the number of features will decrease. When not performing the feature fusion, since the number of features included in the learning data is 10 in total, the number of features may decrease by 40%, which may be equivalent to a 40% reduction in the number of nodes of the input layer, and it may be possible to obtain the effect of considerably reducing the amount of calculation of machine learning.

When generation of the learning data using the current measurement gauge is finished, the proximity correction model learner may repeat generation of learning data for the next measurement gauge, until there are no remaining measurement gauges in the currently being analyzed photographic image (S282, S285). Furthermore, when the learning data generation work for the currently being analyzed photographic image is finished, the proximity correction model learner may repeat the learning data generation for the next photographic image, until all photographic images included in the photographic image acquired in stage S100 are processed (S290, S295).

As mentioned above, the value of etch skew may be determined in various ways depending on how the absolute coordinates of the first evaluation point are determined. This will be explained in detail with reference to FIGS. 9 and 10.

First, explanation will be made with reference to FIG. 9. In some embodiments, a first evaluation point 63a-1 may be set on the contour of the ADI target layer of the mask, as shown in FIG. 9. A region 91 removed in the primary photolithography process of the LELE process, a region 92 removed in the primary etching process, and a region 93 removed in the final etching process will be different from each other by the proximity effect. Therefore, when the final point 66 corresponding to the first evaluation point 63a-1 is set on the contour of the final pattern formed on the device layer, an interval 66a between the absolute coordinates of the final point 66 and the first evaluation point 63a-1 may be determined. The value of the etch skew may be determined using the determined interval 66a.

Next, the explanation will be made with reference to FIG. 10. In some embodiments, as shown in FIG. 10, the first evaluation point 63a-2 may be set on the contour of the layer of the photoresist pattern formed by the primary photolithography process. In this case, unlike the case described with reference to FIG. 9, the value of the etch skew may be determined even in a situation in which the ADI target layer of the mask has not been determined. When the final point 66 corresponding to the first evaluation point 63a-2 is set on the contour of the final pattern formed on the device layer, an interval 66b between absolute coordinates of the final point 66 and the first evaluation point 63a-1 will be determined. The value of the etch skew may be determined, using the determined interval 66b.

Next, the proximity correction execution process for the LELE process will be described in greater detail with reference to FIG. 11. For ease of understanding, the explanation will be made assuming that stage S400 is performed by the service server 200.

The service server acquires mask layer data to be adjusted (S410). Unlike the learning process of the proximity correction model explained with reference to FIG. 5, only data about the mask layer exist in the proximity correction execution process for the LELE process, and there may not be a situation in which the measurement gauge is displayed on the image photographed as a result of performing the LELE process. Therefore, in order to set the first evaluation point on the mask layer and the second evaluation point on the reference layer, the service server may perform a dissection procedure that divides the mask layer into a plurality of segment units (S420). The dissection procedure may be a procedure for cutting the contour of the mask layer into a plurality of segment units according to predetermined rules, and may be performed using function provided by existing OPC tool.

The service server may repeatedly perform an operation of setting the first evaluation point for each of a plurality of segments set in the target mask layer. The service server may start a learning data generation work for the first segment (S430).

The service server may set the first evaluation point in the current segment (S430). For example, the center point of the current segment may be set as the first evaluation point.

The service server may determine a second evaluation point on the reference layer, using the first evaluation point (S440). The service server may determine the second evaluation point to satisfy conditions in which the direction of the first segment to which the first evaluation point belongs is the same as the direction of the second segment to which the second evaluation point belongs, the distance between the first segment and the second segment is minimum, and the second evaluation point belonging to the second segment has the minimum distance between the first evaluation points.

As shown in FIG. 12, first evaluation points 63o to 63t may be set at the center points of each of a plurality of segments 60a to 60e formed on the contour 60 of the main layer, and a plurality of segments may also be formed in the contour 61 by the same criteria as the contour 60 of the main layer. At this time, it should be noted that the center point of the segment may be set by the OPC tool, the plurality of center points may be set for each segment, and each center point is set using importance from the perspective of the evaluation but should not be set in the middle of the segment.

At this time, the second evaluation point may be determined to satisfy the conditions in which the direction of the first segment to which the first evaluation points 63o to 63t belong is the same as the direction of the second segment to which the second evaluation points 64o to 64t belong, the distance between the first segment and the second evaluation is minimum, and the second evaluation points belonging to the second segment have the minimum distance between the first evaluation points. By determining the second evaluation point in this way, the first evaluation point and the second evaluation point may have a one-to-one correspondence relationship (e.g., a reliable one-to-one correspondence relationship).

The explanation will be made by returning to FIG. 11 again. The service server may generate a value of the first feature set including various information such as the geometric feature of the first evaluation point (S450), may generate a value of the second feature set including various types of information such as the geometric feature of the second evaluation point, (S455), and may generate an input vector of the first evaluation point including the first feature set and the second feature set (S460).

As it is widely known, the process of generating input vectors in the machine learning stage (training stage) and the inferring stage may be symmetric. Therefore, the example described with reference to FIGS. 7 and 8 may be similarly applied to the process of generating the input vector of the first evaluation point including the first feature set and the second feature set.

For example, the number of features included in the first feature set is greater than the number of features included in the second feature set, and some of the features included in the first feature set may be included in the second feature set, the first feature set may include a visible_space feature, and the second feature set may also include a visible_space feature. Further, the input vector may include values of each of a first fusion feature to a n^{th} fusion feature which are results of the feature fusion of each of a first feature to a n^{th} feature of the first feature set and the second feature set, some of the features included in the first feature set may be included in the second feature set, and the input vector may further include values of each of the one or more features not included in the second feature set.

Next, the service server may input the generated input vector into a proximity correction model learned in advance, and may acquire the value of the etch skew for the first evaluation point, using the data that is output from the proximity correction model (S470).

The service server may then calculate the position of the final point corresponding to the first evaluation point, by using the acquired value of the etch skew. The final point may be a point on the final pattern on the device layer formed by the final etching process for the LELE process, and may be understood as the position after the proximity effect of the first evaluation point occurs.

Next, the service server may repeat the first evaluation point setting of each segment and the etch skew value calculation work, until the processing for each segment is finished (S485, S486). The service server may calculate the etch skew value for each of the plurality of first evaluation points on the target mask layer and calculate the position after the occurrence of the proximity effect using the value of the etch skew, thereby generating the inferring result of the final pattern formed according to the LELE process, and rendering information on the inferring result and sending it to the user terminal (S490).

In addition, in the LELE process, because each of the photolithography process and etching process based on the first mask, and the photolithography process and etching process based on the second mask is performed independently, the service server may, of course, perform the operation of FIG. 11, which is performed on the first mask, also on the second mask. However, even if the operation of FIG. 11 is performed on the second mask, the reference layer may be the same. This is because, as described above, the reference layer may be formed by performing an OR instruction on the target ACI (After Cleaning Inspection) of the first mask and the target ACI of the second mask.

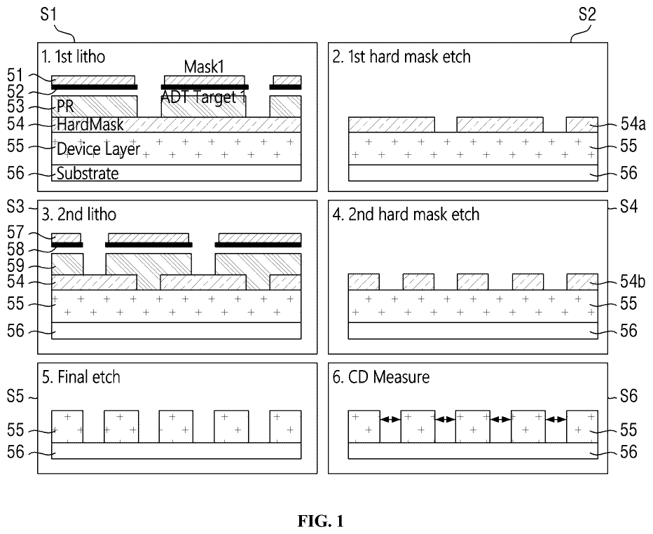

Technical ideas that may be understood through the examples described above with reference to FIGS. 1 to 12 may be reflected in other examples described later, although not specifically stated.

FIG. 13 is a hardware configuration diagram of a computing system 1000 according to some embodiments of the present disclosure. The computing system 1000 of FIG. 13 may refer to, for example, the proximity correction model learner 100 or the service server 200 described with reference to FIG. 1. The computing system 1000 may include one or more processors 1100, a system bus 1600, a communication interface 1200, a memory 1400 for loading a computer program 1500 performed by the processor 1100, and a storage 1300 for storing the computer program 1500.

The processor 1100 may be configured to control the overall operation of each component of the computing system 1000. The processor 1100 may perform calculation on at least one application or program for executing method/operation according to various examples of the present disclosure. The memory 1400 may store various types of data, instructions and/or information. The memory 1400 may load one or more computer programs 1500 from the storage 1300 and may execute methods/operations according to various implementations of the present disclosure. The system bus 1600 may provide a communication function between components of the computing system 1000. The communications interface 1200 may support Internet communications or network communications of the computing system 1000. The storage 1300 may non-temporarily store one or more computer programs 1500. Further, the storage 1300 may store learning data 1800 and executable data of computer programs.

The computer program 1500 may include one or more instructions in which methods/operations according to various examples of the present disclosure are implemented. When the computer program 1500 is loaded into the memory 1400, the processor 1100 may perform methods/operations according to various examples of the present disclosure by executing one or more instructions.

Meanwhile, data 1700 that defines a proximity correction model may be loaded into the memory 1400. The data 1700 may include, for example, parameters and hyperparameters of the proximity correction model. Further, the memory 1400 may also store the learning data 1800 for learning the proximity correction model. The learning data 1800 may be received through the communication interface 1200.

It will be clearly understood that the computer program 1500 may be formed to include instructions for implementing methods that may be understood through some of the examples described above.

For example, when the computer program 1500 is a program for generating the proximity correction model for the LELE process, the computer program 1500 may include an instruction for acquiring data of a measurement gauge on a measurement image in which a first mask layer, which may be an ADI (After Development Inspection) image of a photoresist pattern formed by a primary photolithography process using the first mask, and a reference layer corresponding to a hard mask formed by the primary photolithography process and the primary etching process using the first mask, and the secondary photolithography process and the secondary etching process using the second mask are overlaid; an instruction for determining a first evaluation point which may be a point on which the measurement gauge and a contour of the first mask layer intersect; an instruction for determining a second evaluation point which may be a point on which the measurement gauge and a contour of the reference layer intersect; an instruction for determining a final point corresponding to the first evaluation point on a contour of a final pattern formed after a final etching process using the hard mask; an instruction for generating a value of an etch skew of the first evaluation point by comparing coordinates of the first evaluation point with coordinates of the final point; an instruction for generating a first feature set of the first evaluation point; an instruction for generating a second feature set of the second evaluation point; an instruction for generating learning data including information on the first feature set, information on the second feature set, and the etch skew; and an instruction for performing supervised learning on the proximity correction model, using the learning data.

Further, when the computer program 1500 is a program for performing proximity correction in the LELE process, the computer program 1500 may include an instruction for acquiring a first feature set of the first evaluation point (EP) of the first mask; an instruction for acquiring a second feature set of a second evaluation point of a reference layer corresponding to the hard mask formed by the primary photolithography process and primary etching process using the first mask, and the secondary photolithography process and secondary etching process using the second mask; an instruction for inputting input data including information of the first feature set and information of the second feature set into the proximity correction model; an instruction for generating a value of an etch skew of the first evaluation point of the first mask, using data that is output from the proximity correction model; and an instruction for generating an etch skew value of the plurality of first evaluation points of the first mask, visualizing and generating an inferring result of the final pattern formed on the device layer using the generated etch skew values, and sending the inferring result of the final pattern to the user terminal.

In some embodiments, the computing system 1000 described with reference to FIG. 13 may be formed, using one or more physical servers included in a server farm on the basis of a cloud technique, such as a virtual machine. In this case, among the components shown in FIG. 9, at least some of the processor 1100, the memory 1400, and the storage 1300 may be virtual hardware, and the communication interface 1200 may also be formed by virtualized networking elements such as a virtual switch.

Various embodiments of the present inventive concepts and effects according to the embodiments have been described with reference to FIGS. 1 to 13. The effects according to the technical idea of the present inventive concepts are not limited to the effects mentioned above, and other effects not described can be clearly understood by those skilled in the art from the description above.

The technical ideas of the present disclosure described so far can be implemented as computer-readable code on a computer-readable medium. The computer program recorded on the computer-readable recording medium can be transmitted to another computing device through a network such as the Internet, installed on the other computing device, and thus used on the other computing device.

Although operations are shown in a specific order in the drawings, it should be understood that the present disclosure is not limited to the specific order shown, and that desired results may be obtained only when the operations must be performed in the specific order or when all of the operations must be performed. In certain situations, multitasking and parallel processing may be advantageous. Although embodiments of the present inventive concepts have been described above with reference to the attached drawings, those skilled in the art will understand that the present disclosure may be implemented in other specific forms without changing the technical idea or essential features. The embodiments described above should be understood in all respects as illustrative and not restrictive. The scope of protection of the present invention should be interpreted in accordance with the claims below, and all technical ideas within the equivalent scope should be construed as being included in the scope of rights of the technical ideas defined by this disclosure.

1. A proximity correction system for a litho-etching-litho-etching (LELE) process, the system comprising:
a memory configured to load data that defines a proximity correction model and a proximity correction program of the LELE process; and
one or more processors configured to execute the proximity correction program,
wherein the proximity correction program includes:
an instruction for acquiring a first feature set of a first evaluation point of a first mask;
an instruction for acquiring a second feature set of a second evaluation point of a reference layer corresponding to a hard mask which is formed by a primary photolithography process and a primary etching process using the first mask, and a secondary photolithography process and a secondary etching process using a second mask;
an instruction for inputting input data including information of the first feature set and information of the second feature set into the proximity correction model; and
an instruction for generating a value of an etch skew of the first evaluation point of the first mask, using data that is output from the proximity correction model,
wherein the second evaluation point corresponds to the first evaluation point.

2. The proximity correction system for the LELE process of claim 1,
wherein the instruction for acquiring the first feature set includes:
an instruction for dividing a layer of the first mask into a plurality of segments, using a dissection function of OPC (Optical Proximity Correction); and
an instruction for determining the first evaluation point in a first segment among the plurality of segments.

3. The proximity correction system for the LELE process of claim 2, wherein the instruction for determining the first evaluation point includes an instruction for determining a midpoint of the first segment as the first evaluation point.

4. The proximity correction system for the LELE process of claim 2,
wherein the instruction for acquiring the second feature set of the second evaluation point of the reference layer includes an instruction for determining the second evaluation point of the reference layer, using the first evaluation point, and
wherein a direction of the first segment to which the first evaluation point belongs is identical to a direction of a second segment to which the second evaluation point belongs, a distance between the first segment and the second segment is a minimum, and the second evaluation point belonging to the second segment has a minimum distance between the first evaluation points.

5. The proximity correction system for the LELE process of claim 1, wherein the instruction for acquiring the second feature includes an instruction for forming the reference layer by performing an OR instruction on a target ACI (After Cleaning Inspection) of the first mask and a target ACI of the second mask.

6. The proximity correction system for the LELE process of claim 1,
wherein the etch skew of the first evaluation point refers to a difference between a position corresponding to the first evaluation point of an ADI (After Development Inspection) of a photoresist pattern formed as a result of the primary photolithography process using the first mask, and a position to the first evaluation point of final pattern formed after the final etching process.

7. The proximity correction system for the LELE process of claim 1,
wherein a number of features included in the first feature set is larger than a number of features included in the second feature set.

8. The proximity correction system for the LELE process of claim 7,
wherein some of the features included in the first feature set are included in the second feature set.

9. The proximity correction system for the LELE process of claim 8,
wherein the first feature set includes a visible space feature, and the second feature set also includes a visible space feature.

10-12. (canceled)

13. A proximity correction method for a litho-etching-litho-etching (LELE) process performed by a computing system, the method comprising:
acquiring a first feature set of a first evaluation point of a first mask;
acquiring a second feature set of a second evaluation point of a reference layer corresponding to a shape of a hard mask which is formed by a primary photolithography process and a primary etching process using the first mask, and a secondary photolithography process and a secondary etching process using a second mask;
inputting input data including the first feature set and the second feature set into the proximity correction model; and
generating a value of an etch skew of the first evaluation point of the first mask, using data that is output from the proximity correction model,
wherein the second evaluation point corresponds to the first evaluation point.

14. The proximity correction method for the LELE process of claim 13, further comprising:
performing a layout correction for the first evaluation point of the first mask, by using the value of the etch skew of the first evaluation point and a target ACI of a final etching process using the hard mask.

15. The proximity correction method for the LELE process of claim 14, further comprising:
repeatedly acquiring the first feature set, acquiring the second feature set, inputting, generating the value of the etch skew, and performing the layout correction, while changing the first evaluation point of the first mask.

16. A proximity correction model generation system for a litho-etching-litho-etching (LELE) process, the system comprising:
a memory configured to load data that defines a proximity correction model and a proximity correction model learning program of the LELE process; and
one or more processors configured to execute the proximity correction model learning program,
wherein the proximity correction model learning program includes:
an instruction for acquiring data of a measurement gauge on a measurement image in which a first mask layer, which is an ADI (After Development Inspection) image of a photoresist pattern formed by a primary photolithography process using a first mask, and a reference layer corresponding to a hard mask formed by the primary photolithography process and the primary etching process using the first mask, and a secondary photolithography process and a secondary etching process using a second mask are overlaid;
an instruction for determining a first evaluation point which is a point on which the measurement gauge and a contour of the first mask layer intersect;
an instruction for determining a second evaluation point which is a point on which the measurement gauge and a contour of the reference layer intersect;
an instruction for determining a final point corresponding to the first evaluation point on a contour of a final pattern formed after a final etching process using the hard mask;
an instruction for generating a value of an etch skew of the first evaluation point, by comparing coordinates of the first evaluation point with coordinates of the final point;
an instruction for generating a first feature set of the first evaluation point;
an instruction for generating a second feature set of the second evaluation point;
an instruction for generating learning data including information on the first feature set, information on the second feature set, and the etch skew; and
an instruction for performing supervised learning on the proximity correction model, using the learning data,
wherein the second evaluation point corresponds to the first evaluation point.

17. The proximity correction model generation system for the LELE process of claim 16,
wherein a number of features included in the first feature set is greater than a number of features included in the second feature set.

18. The proximity correction model generation system for the LELE process of claim 17,
wherein some of the features included in the first feature set are included in the second feature set.

19. The proximity correction model generation system for the LELE process of claim 18,
wherein the first feature set includes a visible space feature, and the second feature set also includes a visible space feature.

20. The proximity correction model generation system for the LELE process of claim 16,
wherein the instruction for generating the learning data includes
an instruction for generating an input vector, using features of the first feature set and features of the second feature set, and
the input vector includes values of each of a first fusion feature to an n^{th} fusion feature which are results of feature fusion of values of each of a first feature to an n^{th} feature of the first feature set and the second feature set.
